(19) United States
(12) Patent Application Publication
(10) Pub. No.: US 2026/0243853 A1
(43) Pub. Date: Aug. 20, 2026

(54) MAGNETIC FIELD SCANNING METHOD AND SYSTEM

(71) Applicant: GM GLOBAL TECHNOLOGY OPERATIONS LLC, Detroit, MI (US)

(72) Inventors: Darien Carson, Royal Oak, MI (US); Peng Peng, Rochester Hills, MI (US); Alireza Fatemi, Canton, MI (US); Thomas W. Nehl, Shelby Twp., MI (US)

(73) Assignee: GM GLOBAL TECHNOLOGY OPERATIONS LLC, Detroit, MI (US)

(21) Appl. No.: 19/059,011

(22) Filed: Feb. 20, 2025

(51) Int. Cl. G01R 33/10; H02K 21/14

(52) U.S. Cl. CPC G01R 33/10; H02K 21/14

(57) ABSTRACT

A measurement system for characterizing a magnetic flux density of a magnet including a magnetic field probe, including a Gauss meter, for detecting a plurality of magnetic flux density magnitudes at a plurality of points proximate to a surface of the magnet, a magnet holder for mechanically restraining the magnet, a positioner for positioning the magnet with respect to the magnetic field probe at each of the plurality of points, a processor for receiving each of the plurality of magnetic flux density magnitudes and for generating a spatial representation of the magnetic flux density of the magnet, and a memory for receiving the spatial representation of the magnetic flux density of the magnet from the processor and for storing the spatial representation of the magnetic flux density of the magnet.

### GOVERNMENT FUNDING

This invention was made with Government support under Agreement No.: DE-AR0001564, awarded by the United States Department of Energy. The Government may have certain rights in this invention.

### INTRODUCTION

The present disclosure generally relates to automotive electrical systems and electric vehicle propulsion systems, and more particularly relates to a method and apparatus to scan a magnetic field of a magnet to generate a spatial representation of the magnetic flux density distribution of the magnet in order to predict a performance of a permanent magnet synchronous motor in response to the spatial representation of the magnetic flux density distribution of at least one permanent magnet.

Modern electric vehicles offer sustainable and efficient transportation. Powered by electric motors, electric vehicles deliver instant torque, resulting in smooth and responsive acceleration. Electric motors are used in electric vehicles to convert electrical energy from the battery into mechanical energy to turn the wheels. Typically, there are two main types of electric motors used in electric vehicles: induction motors and permanent magnet synchronous motors (PMSMs). A PMSM is a type of electric motor characterized by the use of permanent magnets on its rotor to generate the magnetic field thereby eliminating the need for separate excitation windings. In a PMSM, the rotor rotates at the same speed as the rotating magnetic field produced by the stator windings, ensuring synchronous operation. PMSMs are often used in high-performance electric vehicles, such as sports cars and racing cars due to their high performance and energy efficiency. Modern electric vehicles typically have two electric motors, one for each axle, but some electric vehicles can have a single motor located under the hood or four motors, one for each wheel. Regenerative braking technology further enhances efficiency by capturing kinetic energy during deceleration and converting it into electricity. As battery technology advances, electric vehicles are becoming increasingly practical for everyday use, with longer ranges, faster charging times, and lower maintenance costs. The expanding charging infrastructure provides convenience and peace of mind, making electric vehicle ownership more accessible than ever before. Furthermore, other desirable features and characteristics of the present disclosure will become apparent from the subsequent detailed description and the appended claims, taken in conjunction with the accompanying drawings and the foregoing technical field and background.

### SUMMARY

Disclosed herein are vehicle propulsion methods and systems and related electrical systems for converting electric energy into a vehicle propulsion force, methods for making and methods for operating such systems, and motor vehicles and other equipment such as aircraft, trucks, buses, forklifts, construction vehicles and other electric vehicles equipped with auxiliary power outlets. By way of example, and not limitation, there are presented various embodiments of systems for predicting a performance of a permanent magnet synchronous motor in an electric machine by characterizing a magnetic flux density of a magnet within the permanent magnet synchronous motor.

In accordance with an aspect of the present disclosure, a measurement system for characterizing a magnetic flux density of a magnet including a magnetic field probe, including a Gauss meter, for detecting a plurality of magnetic flux density magnitudes at a plurality of points proximate to a surface of the magnet, a magnet holder for mechanically restraining the magnet, a positioner for positioning the magnet with respect to the magnetic field probe at each of the plurality of points, a processor for receiving each of the plurality of magnetic flux density magnitudes and for generating a spatial representation of the magnetic flux density of the magnet, and a memory for receiving the spatial representation of the magnetic flux density of the magnet from the processor and for storing the spatial representation of the magnetic flux density of the magnet.

In accordance with another aspect of the present disclosure, wherein the positioner is a three-dimensional positioner for moving the magnetic field probe within a three dimensional space proximate to the surface of the magnet.

In accordance with another aspect of the present disclosure, wherein the positioner is configured to rotate the magnet holder and to tilt the magnet holder radially from an axis orthogonal to the surface of the magnet.

In accordance with another aspect of the present disclosure, wherein the positioner is configured to vary a distance between the magnet holder and the magnetic field probe along an axis orthogonal to the surface of the magnet.

In accordance with another aspect of the present disclosure, wherein the spatial representation of the magnetic flux density of the magnet is stored in the memory and is correlated to a cartesian coordinate system.

In accordance with another aspect of the present disclosure, wherein the spatial representation of the magnetic flux density of the magnet is stored in the memory and is correlated to a polar coordinate system.

In accordance with another aspect of the present disclosure, wherein the processor is further operative to perform a numerical modelling algorithm in response to the spatial representation of the magnetic flux density of the magnet to predict a future spatial representation of the magnetic flux density.

In accordance with another aspect of the present disclosure, wherein the processor is further operative to perform a numerical modelling algorithm in response to the spatial representation of the magnetic flux density of the magnet to predict a performance of a permanent magnet synchronous motor.

In accordance with another aspect of the present disclosure, further including a display for displaying a graphical representation of the spatial representation of the magnetic flux density.

In accordance with another aspect of the present disclosure, a method for characterizing a magnetic flux density of a magnet including restraining, by a magnet holder, the magnet, positioning, by a magnet holder positioner, the magnet with respect to the magnetic field probe at each of the plurality of points, detecting, by the magnetic field probe, a plurality of magnetic flux density magnitudes at a plurality of points proximate to a surface of the magnet, generating a spatial representation of the magnetic flux density of the magnet by a processor in response to the plurality of magnetic flux density magnitudes, and storing the spatial representation of the magnetic flux density of the magnet by a memory in response to receiving the spatial representation of the magnetic flux density of the magnet from the processor.

In accordance with another aspect of the present disclosure, wherein the positioner is a three-dimensional positioner for moving the magnetic field probe within a three-dimensional space proximate to the surface of the magnet.

In accordance with another aspect of the present disclosure, wherein the spatial representation of the magnetic flux density of the magnet is stored in the memory and is correlated to a cartesian coordinate system.

In accordance with another aspect of the present disclosure, wherein the positioner is configured to rotate the magnet holder and to tilt the magnet holder radially from an axis orthogonal to the surface of the magnet.

In accordance with another aspect of the present disclosure, wherein the spatial representation of the magnetic flux density of the magnet is stored in the memory and is correlated to a polar coordinate system.

In accordance with another aspect of the present disclosure, wherein the positioner is configured to vary a distance between the magnet holder and the magnetic field probe along an axis orthogonal to the surface of the magnet.

In accordance with another aspect of the present disclosure, wherein the processor is further operative to perform a numerical modelling algorithm in response to the spatial representation of the magnetic flux density of the magnet to predict a future spatial representation of the magnetic flux density.

In accordance with another aspect of the present disclosure, wherein the processor is further operative to perform a numerical modelling algorithm in response to the spatial representation of the magnetic flux density of the magnet to predict a performance of a permanent magnet synchronous motor.

In accordance with another aspect of the present disclosure, further including a display for displaying a graphical representation of the spatial representation of the magnetic flux density.

In accordance with another aspect of the present disclosure, an apparatus for characterizing a performance of a permanent magnet synchronous motor including a memory for storing a plurality of spatial representations of magnetic flux densities associated with a plurality of permanent magnet synchronous motor performance parameters, a magnetic field probe, including a Gauss meter, for detecting a plurality of magnetic flux density magnitudes at a plurality of points proximate to a surface of a permanent magnet, a positioner for positioning the magnetic field probe with respect to the permanent magnet at each of the plurality of points, and a processor for receiving each of the plurality of magnetic flux density magnitudes and for generating a spatial representation of the magnetic flux density of the permanent magnet and for comparing the spatial representation of the magnetic flux density to the plurality of spatial representations of magnetic flux densities to estimate the performance of the permanent magnet synchronous motor in response to at least one of the plurality of permanent magnet synchronous motor performance parameters.

In accordance with another aspect of the present disclosure, wherein the processor is further operative to perform a numerical modelling algorithm in response to the spatial representation of the magnetic flux density of the magnet to predict a future spatial representation of the magnetic flux density and wherein the future spatial representation of the magnetic flux density is compared to the a plurality of spatial representations of magnetic flux densities to generate a first performance parameter associated with a current magnet condition and a second performance parameter associated with a future magnet condition.

### BRIEF DESCRIPTION OF THE DRAWINGS

The exemplary embodiments will hereinafter be described in conjunction with the following drawing figures, wherein like numerals denote like elements, and wherein:

FIG. 1 shows a control system associated with a vehicle in accordance with various embodiments;

FIG. 2 shows a cross section of an exemplary permanent magnet synchronous motor in accordance with various embodiments;

FIG. 3 shows an exemplary configuration of a three-axis magnetic field scanner in accordance with various embodiments;

FIG. 4 shows an exemplary configuration of a magnetic field scanner for scanning curved magnets in accordance with various embodiments; and

FIG. 5 shows exemplary three-dimensional flux density maps in accordance with various embodiments.

### DETAILED DESCRIPTION

The following detailed description is merely exemplary in nature and is not intended to limit the application and uses. Furthermore, there is no intention to be bound by any expressed or implied theory presented in the preceding technical field, background, brief summary, or the following detailed description. As used herein, the term “module” refers to any hardware, software, firmware, electronic control component, processing logic, and/or processor device, individually or in any combination, including without limitation: application-specific integrated circuit (ASIC), a field-programmable gate array (FPGA), an electronic circuit, a processor (shared, dedicated, or group) and memory that executes one or more software or firmware programs, a combinational logic circuit, and/or other suitable components that provide the described functionality.

Embodiments of the present disclosure may be described herein in terms of functional and/or logical block components and various processing steps. It should be appreciated that such block components may be realized by any number of hardware, software, and/or firmware components configured to perform the specified functions. For example, an embodiment of the present disclosure may employ various integrated circuit components, e.g., memory elements, digital signal processing elements, logic elements, lookup tables, or the like, which may carry out a variety of functions under the control of one or more microprocessors or other control devices. In addition, those skilled in the art will appreciate that embodiments of the present disclosure may be practiced in conjunction with any number of systems and that the systems described herein are merely exemplary embodiments of the present disclosure.

For the sake of brevity, conventional techniques related to signal processing, data transmission, signaling, control, machine learning, image analysis, and other functional aspects of the systems (and the individual operating components of the systems) may not be described in detail herein. Furthermore, the connecting lines shown in the various figures contained herein are intended to represent example functional relationships and/or physical couplings between the various elements. It should be noted that many alternative or additional functional relationships or physical connections may be present in an embodiment of the present disclosure.

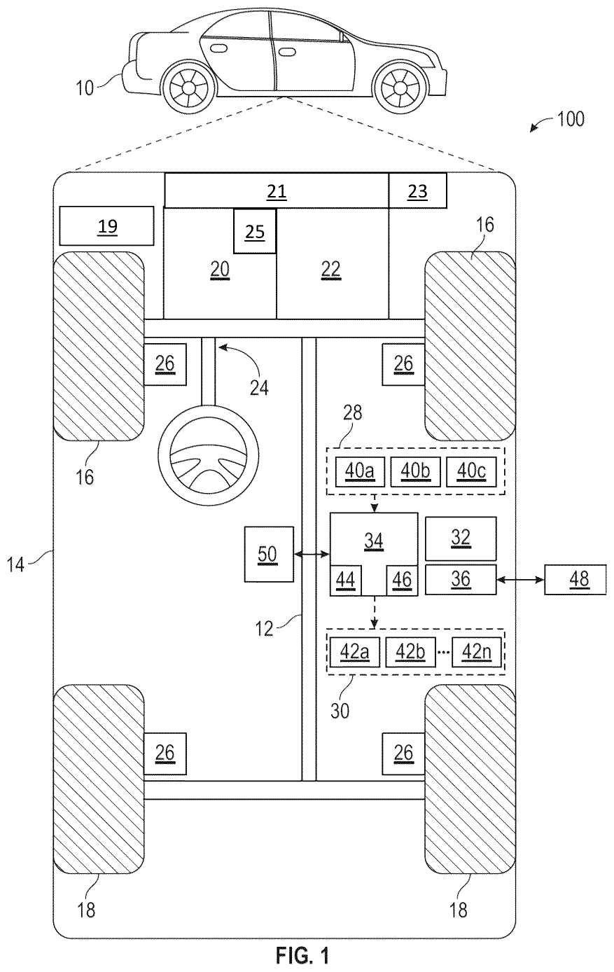

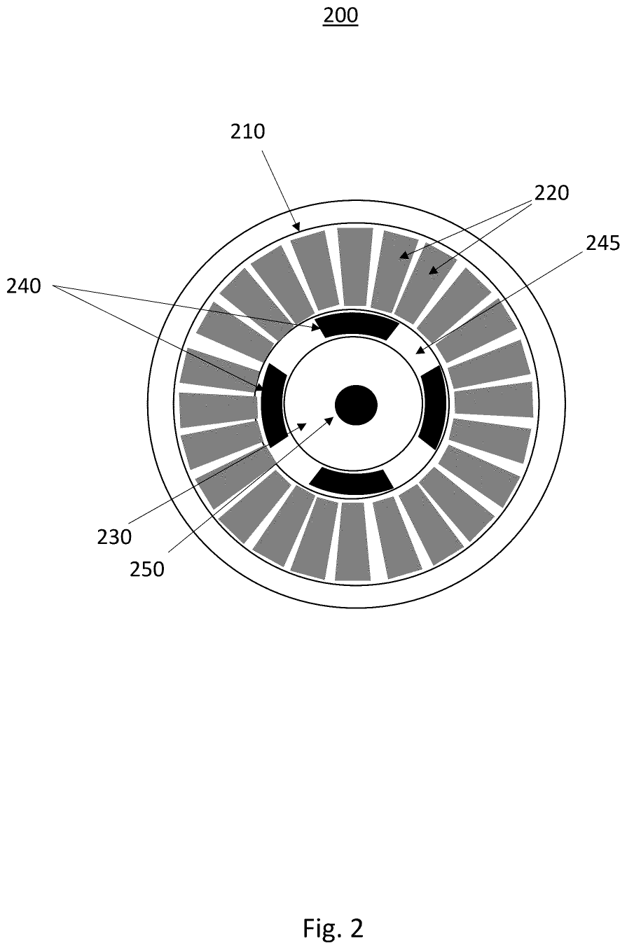

With reference to FIG. 1, a control system 100 is associated with a vehicle 10 (also referred to herein as a “host vehicle”) in accordance with various embodiments. In general, the control system (or simply “system”) 100 provides for control of various actions of the vehicle 10 (e.g., torque control) established by Reinforcement Learning (RL) which is or can be stored in a deep neural network (DNN) type model that controls operation in response to data from vehicle inputs, for example, as described in greater detail further below in connection with FIGS. 2-4.

In various exemplary embodiments, system 100 provides a process using an algorithm that controls torque and speed in a host vehicle's 10 embedded controller software of the system 100 allowing DNN to be used for an automated cruise control behavior prediction model. The system 100 enables learning of driver's preference for following distance for different vehicles such a target vehicle and to classify driver's preference based on driving scenarios; e.g., traffic signs, stop and go traffic, city driving, and the like. The system 100 uses a quadrature matrix to build a knowledge base for target vehicles following a performance preference by utilizing online and historical driver and environmental information.

As depicted in FIG. 1, vehicle 10 generally includes a chassis 12, a body 14, front wheels 16, and rear wheels 18. The body 14 is arranged on the chassis 12 and substantially encloses components of the vehicle 10. The body 14 and the chassis 12 may jointly form a frame. The wheels 16-18 are each rotationally coupled to the chassis 12 near a respective corner of the body 14. In various embodiments, the wheels 16, 18 include a wheel assembly that also includes respectively associated tires.

In various embodiments, vehicle 10 is autonomous or semi-autonomous, and the control system 100, and/or components thereof, are incorporated into the vehicle 10. The vehicle 10 is, for example, a vehicle that is automatically controlled to carry passengers from one location to another. The vehicle 10 is depicted in the illustrated embodiment as a passenger car, but it should be appreciated that any other vehicle, including motorcycles, trucks, sport utility vehicles, recreational vehicles, marine vessels, aircraft, and the like, can also be used.

As shown, the vehicle 10 generally includes a propulsion system 20, a transmission system 22, a steering system 24, a brake system 26, a canister purge system 31, one or more user input devices 27, a sensor system 28, an actuator system 30, at least one data storage device 32, at least one controller 34, and a communication system 36. The propulsion system 20 may, in various embodiments, an electric machine such as a traction motor 25, a battery 21, an inverter 19 for converting direct current (DC) from the battery to alternating current (AC) current to be supplied to the electric machine, and an on board charger 23 for converting AC current from an external power source to a DC current to be used to charge the battery 21. In some exemplary embodiments, the traction motor 25 can be a permanent magnet synchronous motor (PMSM), The transmission system 22 is configured to transmit power from the propulsion system 20 to the vehicle wheels 16 and 18 according to selectable speed ratios. According to various embodiments, the transmission system 22 may include a step-ratio automatic transmission, a continuously variable transmission, or other appropriate transmissions.

The brake system 26 is configured to provide braking torque to the vehicle wheels 16 and 18. Brake system 26 may, in various embodiments, include friction brakes, brake by wire, a regenerative braking system such as an electric machine, and/or other appropriate braking systems.

The steering system 24 influences the position of the vehicle wheels 16 and/or 18. While depicted as including a steering wheel for illustrative purposes, in some embodiments contemplated within the scope of the present disclosure, the steering system 24 may not include a steering wheel.

The controller 34 includes at least one processor 44 (and neural network 33) and a computer-readable storage device or media 46. As noted above, in various embodiments, the controller 34 (e.g., the processor 44 thereof) provides data pertaining to a projected future path of the vehicle 10, including projected future steering instructions, to the steering control system 84 in advance, for use in controlling steering for a limited period of time in the event that communications with the steering control system 84 become unavailable. Also, in various embodiments, the controller 34 provides communications to the steering control system 84 via the communication system 36 described further below, for example, via a communication bus and/or transmitter (not depicted in FIG. 1).

In various embodiments, controller 34 includes at least one processor 44 and a computer-readable storage device or media 46. The processor 44 may be any custom-made or commercially available processor, a central processing unit (CPU), a graphics processing unit (GPU), an auxiliary processor among several processors associated with the controller 34, a semiconductor-based microprocessor (in the form of a microchip or chipset), any combination thereof, or generally any device for executing instructions. The computer-readable storage device or media 46 may include volatile and non-volatile storage in read-only memory (ROM), random-access memory (RAM), and keep-alive memory (KAM), for example. KAM is a persistent or non-volatile memory that may be used to store multiple neural networks, along with various operating variables, while the processor 44 is powered down. The computer-readable storage device or media 46 may be implemented using any of a number of known memory devices such as PROMs (programmable read-only memory), EPROMs (electrically PROM), EEPROMs (electrically erasable PROM), flash memory, or any other electric, magnetic, optical, or combination memory devices capable of storing data, some of which represent executable instructions, used by the controller 34 in controlling the vehicle 10.

The instructions may include one or more separate programs, each of which includes an ordered listing of executable instructions for implementing logical functions. The instructions, when executed by the processor 44, receive and process signals from the sensor system 28, perform logic, calculations, methods, and/or algorithms for automatically controlling the components of the vehicle 10, and generate control signals that are transmitted to the actuator system 30 to automatically control the components of the vehicle 10 based on the logic, calculations, methods, and/or algorithms. Although only one controller 34 is shown in FIG. 1, embodiments of the vehicle 10 may include any number of controllers 34 that communicate over any suitable communication medium or a combination of communication mediums and that cooperate to process the sensor signals, perform logic, calculations, methods, and/or algorithms, and generate control signals to automatically control features of the vehicle 10.

As depicted in FIG. 1, the vehicle 10 generally includes, in addition to the above-referenced steering system 24 and controller 34, a chassis 12, a body 14, front wheels 16, and rear wheels 18. The body 14 is arranged on the chassis 12 and substantially encloses components of the vehicle 10. The body 14 and the chassis 12 may jointly form a frame. The wheels 16-18 are each rotationally coupled to the chassis 12 near a respective corner of the body 14. In various embodiments, the wheels 16, 18 include a wheel assembly that also includes respectively associated tires.

In various embodiments, the vehicle 10 is an autonomous vehicle, and the control system 100, and/or components thereof, are incorporated into the vehicle 10. The vehicle 10 is, for example, a vehicle that is automatically controlled to carry passengers from one location to another. The vehicle 10 is depicted in the illustrated embodiment as a passenger car, but it should be appreciated that any other vehicle, including motorcycles, trucks, sport utility vehicles (SUVs), recreational vehicles (RVs), marine vessels, aircraft, and the like, can also be used.

The controller 34 includes a vehicle controller that operates based on the neural networks 33 model's output. In an exemplary embodiment, a feed-forward operation can be applied for an adjustment factor that is the continuous output of the neural network 33 models to generate a control action for the desired torque or other like action (in case of a continuous neural network 33 models, for example, the continuous prediction values are outputs).

In various embodiments, one or more user input devices 27 receive inputs from one or more passengers (and driver 11) of the vehicle 10. In various embodiments, the inputs include a desired destination of travel for the vehicle 10. In certain embodiments, one or more input devices 27 include an interactive touch-screen in the vehicle 10. In certain embodiments, one or more input devices 27 include a speaker for receiving audio information from the passengers. In certain other embodiments, one or more input devices 27 may include one or more other types of devices and/or maybe coupled to a user device (e.g., smartphone and/or other electronic devices) of the passengers.

The sensor system 28 includes one or more sensors 40a-40n that sense observable conditions of the exterior environment and/or the interior environment of the vehicle 10. The sensors 40a-40n include but are not limited to, radars, lidars, global positioning systems, optical cameras, thermal cameras, ultrasonic sensors, inertial measurement units, and/or other sensors.

The actuator system 30 includes one or more actuators 42a-42n that control one or more vehicle features such as, but not limited to, canister purge system 31, the intake system 38, the propulsion system 20, the transmission system 22, the steering system 24, and the brake system 26. In various embodiments, vehicle 10 may also include interior and/or exterior vehicle features not illustrated in FIG. 1, such as various doors, a trunk, and cabin features such as air, music, lighting, touch-screen display components (such as those used in connection with navigation systems), and the like.

The data storage device 32 stores data for use in automatically controlling the vehicle 10, including the storing of data of a DNN that is established by the RL, used to predict a driver behavior for the vehicle control. In various embodiments, the data storage device 32 stores a machine learning model of a DNN and other data models established by the RL. The model established by the RL can take place for a DNN behavior prediction model or RL established model (See. FIG. 2, DNN prediction model or RL prediction model). In an exemplary embodiment, no separate training is required for the DNN rather, the DNN behavior prediction model (i.e., DNN prediction model) is implemented with a set of learned functions. In various embodiments, the neural network (i.e., DNN behavior prediction model) may be established by RL or trained by a supervised learning methodology by a remote system and communicated or provisioned in vehicle 10 (wirelessly and/or in a wired manner) and stored in the data storage device 32. The DNN behavior prediction model can also be trained via supervised or unsupervised learning based on input vehicle data of a host vehicle operations and/or sensed data about a host vehicles operating environment.

The data storage device 32 is not limited to control data, as other data may also be stored in the data storage device 32. For example, route information may also be stored within data storage device 32—i.e., a set of road segments (associated geographically with one or more of the defined maps) that together define a route that the user may take to travel from a start location (e.g., the user's current location) to a target location. As will be appreciated, the data storage device 32 may be part of controller 34, separate from controller 34, or part of controller 34 and part of a separate system.

Controller 34 implements the logic model established by reinforced learning (RL) or for the DNN based on the DNN behavior model that has been trained with a set of values, including at least one processor 44 and a computer-readable storage device or media 46. The processor 44 may be any custom-made or commercially available processor, a central processing unit (CPU), a graphics processing unit (GPU), an auxiliary processor among several processors associated with the controller 34, a semiconductor-based microprocessor (in the form of a microchip or chipset), any combination thereof, or generally any device for executing instructions. The computer-readable storage device or media 46 may include volatile and non-volatile storage in read-only memory (ROM), random-access memory (RAM), and keep-alive memory (KAM), for example. KAM is a persistent or non-volatile memory that may be used to store various operating variables while the processor 44 is powered down. The computer-readable storage device or media 46 may be implemented using any of a number of known memory devices such as PROMs (programmable read-only memory), EPROMs (electrically PROM), EEPROMs (electrically erasable PROM), flash memory, or any other electric, magnetic, optical, or combination memory devices capable of storing data, some of which represent executable instructions, used by the controller 34 in controlling the vehicle 10.

The instructions may include one or more separate programs, each of which includes an ordered listing of executable instructions for implementing logical functions. The instructions, when executed by the processor 44, receive and process signals from the sensor system 28, perform logic, calculations, methods, and/or algorithms for automatically controlling the components of the vehicle 10, and generate control signals that are transmitted to the actuator system 30 to automatically control the components of the vehicle 10 based on the logic, calculations, methods, and/or algorithms. Although only one controller 34 is shown in FIG. 1, embodiments of the vehicle 10 may include any number of controllers 34 that communicate over any suitable communication medium or a combination of communication mediums and that cooperate to process the sensor signals, perform logic, calculations, methods, and/or algorithms, and generate control signals to automatically control features of the vehicle 10.

The communication system 36 is configured to wirelessly communicate information to and from other entities 48, such as but not limited to, other, infrastructure, remote transportation systems, and/or user devices (described in more detail with regard to FIG. 2). In an exemplary embodiment, the communication system 36 is a wireless communication system configured to communicate via a wireless local area network (WLAN) using wireless network protocol or cellular data communication. However, additional or alternate communication methods, such as a dedicated short-range communications (DSRC) channel, are also considered within the scope of the present disclosure. DSRC channels refer to one-way or two-way short-range to medium-range wireless communication channels specifically designed for automotive use and a corresponding set of protocols and standards.

In various embodiments, the communication system 36 is used for communications between the controller 34, including data pertaining to a projected future path of the vehicle 10, including projected future steering instructions. Also, in various embodiments, the communication system 36 may facilitate communications between the steering control system 84 and/or more other systems and/or devices.

In certain embodiments, the communication system 36 is further configured for communication between the sensor system 28, the input device 27, the actuator system 30, one or more controllers (e.g., the controller 34), and/or more other systems and/or devices. For example, the communication system 36 may include any combination of a controller area network (CAN) bus and/or direct wiring between the sensor system 28, the actuator system 30, one or more controllers 34, and/or one or more other systems and/or devices. In various embodiments, the communication system 36 may include one or more transceivers for communicating with one or more devices and/or systems of the vehicle 10, devices of the passengers, and/or one or more sources of remote information (e.g., GPS data, traffic information, weather information, and so on).

Turning now to FIG. 2, a cross section of an exemplary PMSM 200 is shown in accordance with various embodiments. In an electric vehicle one or more PMSM 200 can be employed as traction motors for propelling the electric vehicle. The PMSM 200 can include a stator 210 including a plurality of stator windings 220, a rotor 230, and a rotor shaft 250. The rotor 230 can further include a plurality of permanent magnets 240 mechanically coupled to the rotor 230, wherein the permanent magnets 240 are separated by a plurality of air gaps 245.

A PMSM 200 operates based on the fundamental principle of electromagnetic induction. A three-phase AC supply is fed to the stator windings 220, which are distributed in a specific configuration to generate a rotating magnetic field. This rotating magnetic field interacts with the constant magnetic field produced by permanent magnets 240 affixed to the rotor 230. These magnetic forces then operate to align the magnetic poles of the rotor 230 with the rotating magnetic field of the stator 210, thereby exerting a torque on the rotor 230 resulting in a rotation of the rotor 230. The rotor 230 rotates at a synchronous speed, which is directly proportional to the frequency of the AC supply and inversely proportional to the number of pole pairs. This synchronous speed is characterized by a constant rotational speed for a given frequency.

Torque production in a PMSM is a result of the interaction between the stator's rotating magnetic field and the rotor's permanent magnet field. The alignment forces between these fields create a torque that drives the rotor. The magnitude of this torque depends on several factors, including the strength of the magnetic fields, the current flowing through the stator windings, and the rotor position. As the rotor rotates, the permanent magnets cut through the magnetic flux lines generated by the stator currents. This induces an electromotive force (EMF) in the stator windings, known as the back EMF. The back EMF opposes the applied voltage and plays a crucial role in regulating the motor's speed and current.

Various control strategies are employed to regulate the speed and torque of a PMSM. These strategies typically involve controlling the magnitude and phase of the three-phase currents supplied to the stator windings. Techniques such as field-oriented control (FOC) and direct torque control (DTC) are commonly used to achieve precise control over the motor's performance. PMSMs offer several advantages, including high efficiency, high power density, and precise controllability. These characteristics make them suitable for a wide range of applications, such as electric vehicles, industrial drives, robotics, and renewable energy systems. Their compact size and high torque-to-weight ratio further enhance their appeal in applications where space and weight are critical considerations.

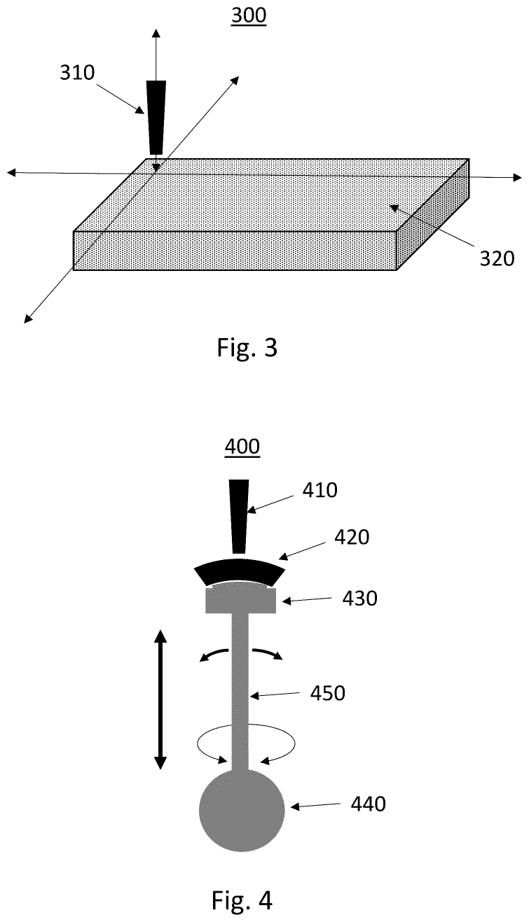

Turning now to FIG. 3, an exemplary configuration 300 of a three-axis magnetic field scanner is shown. The exemplary configuration 300 can include a magnetic field probe 310, such as a Gauss meter, and a magnet under test 320, such as a permanent magnet, such as those used in a PMSM. In some embodiments, the exemplary three axis field scanner is operative to evaluate flux density magnitude over the surface of the magnet under test 320 and can be used as a standard procedure for magnetization quantification.

Accurate measurement of flux density in different magnet types is essential in optimizing motor designs for electric motor power and efficiency. By providing a consistent and reliable method for assessing magnet performance under various operating conditions, the exemplary configuration can aid in advancements in motor technology and enable the development of more efficient electric motors for diverse applications. Additionally, by incorporating detailed flux density characterizations of a diverse range of magnets as training data, the predictive capabilities of numerical simulation models, particularly those based on finite element methods, can be significantly improved. This enhancement in accuracy stems from the model's ability to learn and internalize the complex magnetic behaviors exhibited by different magnet materials. By exposing the model to a rich dataset of flux density profiles, it can develop a deeper understanding of the underlying physical phenomena, leading to more precise and reliable simulation results.

According to exemplary embodiments, the magnetic field probe 310 is configured to scan the volume above the magnet under test 320 at discrete points as referenced in a cartesian coordinate system. The discrete points can be separated by predetermined distances, or steps, such as 0.25 millimeters. In some exemplary embodiments, the exemplary configuration 300 can include a non-magnetic plastic arm mounted on and carried by the linear stages having a 100 millimeter non-magnetic clearance around the magnet to avoid magnetic interference. In some exemplary embodiments, the magnetic field probe 310 can include a Gauss meter embedded at the bottom of the arm. For example, two high-precision Gauss meters can be employed, with a first Gauss meter used for one axis measurement and a second Gauss meter used for three axis flux density measurement. The resulting measurement data can then be used to generate a three-dimensional map of the measured vertical magnet flux density data or in the case of a three-axis sensor, the x, y and z flux densities. The results of the high precision magnet field scan can be utilized to verify existing finite element models. Results can also be used to analyze field strength/distribution prior to design execution.

In some embodiments, the exemplary configuration 300 of the three-axis magnetic field scanner can be operative to measure the flux density magnitude and distribution across the magnet's surface by incorporating synchronized motion control and data logging, featuring precise motorized linear stages for fine control and a three-axis gauss meter for real-time flux density data acquisition. A three-axis manual stage can further be used to enable fine position tuning, thereby offering a variable scanning matrix with adjustable area and step size increments. The exemplary configuration 300 can be further employed with a graphical user interface (GUI) to enable precise move commands, scan parameter settings, and visual output for position and flux data in order to quantify magnet flux behavior, both visually and mathematically, through stored matrix results. In the context of PMSMs, which typically utilize 1.2-1.8 kg of rare-earth permanent magnets, performance and efficiency can be increased through a strategic introduction of ferrite and neodymium magnetic material.

Turning now to FIG. 4, an exemplary configuration 400 of a magnetic field scanner for scanning curved magnets is shown. The exemplary three axis magnetic field scanner of FIG. 3 can be configured to measure both flat and curved magnets by substituting the fixed magnet holder with a rotatable magnet holder, allowing for complete surface scanning. The exemplary configuration 400 can include a magnet under test 420, a magnetic field probe 410, such as a Gauss meter, an angular adjustment device 440, such as a stepper motor, a magnet holder 430 and a vertical support element 450 for mechanically coupling the angular adjustment device 440 to the magnet holder 430. In some exemplary embodiments, t, a vertical height adjustment can be employed by adjusting a length of the vertical support element 450, such that the vertical height is substantially equal to the outer radius of curvature of the arcuate magnet in order to maintain perpendicularity between the magnetic field probe 410 and the surface of the magnet under test 420.

In one or more exemplary embodiments, the angular adjustment device 440 can be configured to rotate the magnet holder 430 radially from the axis of the vertical support element 450 as well as rotationally around the axis of the vertical support element 450. Flux density magnitude can then be measured by the magnetic field probe 410, at both angular and radial increments, thereby generating a three-dimensional map of the flux density magnitude of the magnet under test 420. This three-dimensional map can be referenced to either a cartesian coordinate system or a polar coordinate system.

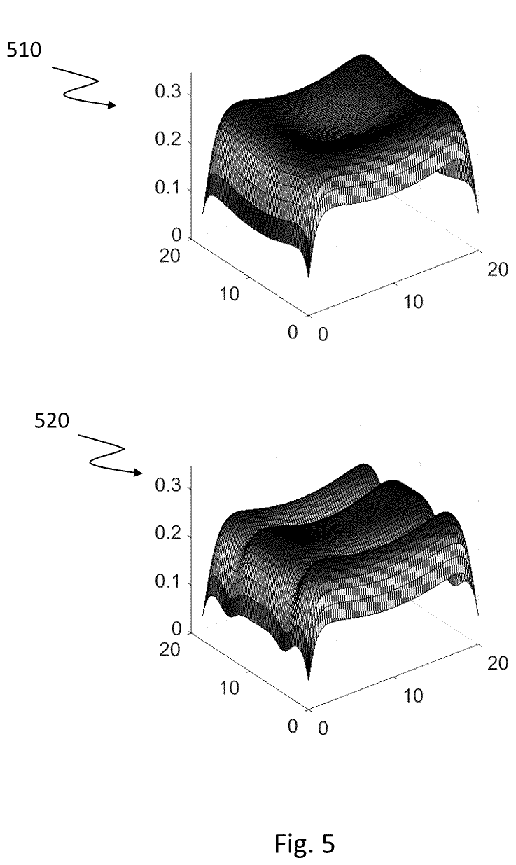

Turning now to FIG. 5, exemplary three-dimensional flux density maps 510, 520 are shown. The exemplary flux density maps 510, 520 are illustrative of flux density measurements resulting from operation of the exemplary configuration 300 of a three-axis magnetic field scanner of FIG. 3. In some exemplary embodiments, the first flux density map 510 can be illustrative of an unused permanent magnetic of a specific material composition, such as a neodymium-iron-boron (NdFeB) magnet, a samarium cobalt (SmCo), or a ferromagnetic alloy. In additional exemplary embodiments, the second flux density map 520 can be illustrative of a previously used permanent magnet or a magnet subjected to know and unknown environmental conditions, such as variations in temperature, exposure to external magnetic fields, or the like. The measured magnetic flux density distributions between new and used magnetics can be used to train numerical method modeling algorithms to determine magnetic flux density over the life of an electric machine.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing the exemplary embodiment or exemplary embodiments. It should be understood that various changes can be made in the function and arrangement of elements without departing from the scope of the disclosure as set forth in the appended claims and the legal equivalents thereof.

What is claimed is:

1. A measurement system for characterizing a magnetic flux density of a magnet comprising:
a magnetic field probe, including a Gauss meter, for detecting a plurality of magnetic flux density magnitudes at a plurality of points proximate to a surface of the magnet;
a magnet holder for mechanically restraining the magnet;
a positioner for positioning the magnet with respect to the magnetic field probe at each of the plurality of points;
a processor for receiving each of the plurality of magnetic flux density magnitudes and for generating a spatial representation of the magnetic flux density of the magnet; and
a memory for receiving the spatial representation of the magnetic flux density of the magnet from the processor and for storing the spatial representation of the magnetic flux density of the magnet.

2. The measurement system for characterizing the magnetic flux density of the magnet of claim 1, wherein the positioner is a three-dimensional positioner for moving the magnetic field probe within a three-dimensional space proximate to the surface of the magnet.

3. The measurement system for characterizing the magnetic flux density of the magnet of claim 1, wherein the positioner is configured to rotate the magnet holder and to tilt the magnet holder radially from an axis orthogonal to the surface of the magnet.

4. The measurement system for characterizing the magnetic flux density of the magnet of claim 1, wherein the positioner is configured to vary a distance between the magnet holder and the magnetic field probe along an axis orthogonal to the surface of the magnet.

5. The measurement system for characterizing the magnetic flux density of the magnet of claim 1, wherein the spatial representation of the magnetic flux density of the magnet is stored in the memory and is correlated to a cartesian coordinate system.

6. The measurement system for characterizing the magnetic flux density of the magnet of claim 1, wherein the spatial representation of the magnetic flux density of the magnet is stored in the memory and is correlated to a polar coordinate system.

7. The measurement system for characterizing the magnetic flux density of the magnet of claim 1, wherein the processor is further operative to perform a numerical modelling algorithm in response to the spatial representation of the magnetic flux density of the magnet to predict a future spatial representation of the magnetic flux density.

8. The measurement system for characterizing the magnetic flux density of the magnet of claim 1, wherein the processor is further operative to perform a numerical modelling algorithm in response to the spatial representation of the magnetic flux density of the magnet to predict a performance of a permanent magnet synchronous motor.

9. The measurement system for characterizing the magnetic flux density of the magnet of claim 1, further including a display for displaying a graphical representation of the spatial representation of the magnetic flux density.

10. A method for characterizing a magnetic flux density of a magnet comprising:
restraining, by a magnet holder, the magnet;
positioning, by a magnet holder positioner, the magnet with respect to a magnetic field probe at each of a plurality of points proximate to a surface of the magnet;
detecting, by the magnetic field probe, a plurality of magnetic flux density magnitudes at the plurality of points proximate to the surface of the magnet;
generating a spatial representation of the magnetic flux density of the magnet by a processor in response to the plurality of magnetic flux density magnitudes; and
storing the spatial representation of the magnetic flux density of the magnet by a memory in response to receiving the spatial representation of the magnetic flux density of the magnet from the processor.

11. The method for characterizing the magnetic flux density of the magnet of claim 10, wherein the magnet holder positioner is a three-dimensional positioner for moving the magnetic field probe within a three-dimensional space proximate to the surface of the magnet.

12. The method for characterizing the magnetic flux density of the magnet of claim 10, wherein the spatial representation of the magnetic flux density of the magnet is stored in the memory and is correlated to a cartesian coordinate system.

13. The method for characterizing the magnetic flux density of the magnet of claim 10, wherein the magnet holder positioner is configured to rotate the magnet holder and to tilt the magnet holder radially from an axis orthogonal to the surface of the magnet.

14. The method for characterizing the magnetic flux density of the magnet of claim 10, wherein the spatial representation of the magnetic flux density of the magnet is stored in the memory and is correlated to a polar coordinate system.

15. The method for characterizing the magnetic flux density of the magnet of claim 10, wherein the magnet holder positioner is configured to vary a distance between the magnet holder and the magnetic field probe along an axis orthogonal to the surface of the magnet.

16. The method for characterizing the magnetic flux density of the magnet of claim 10, wherein the processor is further operative to perform a numerical modelling algorithm in response to the spatial representation of the magnetic flux density of the magnet to predict a future spatial representation of the magnetic flux density.

17. The method for characterizing the magnetic flux density of the magnet of claim 10, wherein the processor is further operative to perform a numerical modelling algorithm in response to the spatial representation of the magnetic flux density of the magnet to predict a performance of a permanent magnet synchronous motor.

18. The method for characterizing the magnetic flux density of the magnet of claim 10, further including a display for displaying a graphical representation of the spatial representation of the magnetic flux density.

19. An apparatus for characterizing a performance of a permanent magnet synchronous motor comprising:
a memory for storing a plurality of spatial representations of magnetic flux densities associated with a plurality of permanent magnet synchronous motor performance parameters;
a magnetic field probe, including a Gauss meter, for detecting a plurality of magnetic flux density magnitudes at a plurality of points proximate to a surface of a permanent magnet;
a positioner for positioning the magnetic field probe with respect to the permanent magnet at each of the plurality of points; and
a processor for receiving each of the plurality of magnetic flux density magnitudes and for generating a spatial representation of a magnetic flux density of the permanent magnet and for comparing the spatial representation of the magnetic flux density to the plurality of spatial representations of magnetic flux densities to estimate the performance of the permanent magnet synchronous motor in response to at least one of the plurality of permanent magnet synchronous motor performance parameters.

20. The apparatus for characterizing the performance of the permanent magnet synchronous motor of claim 19 wherein the processor is further operative to perform a numerical modelling algorithm in response to the spatial representation of the magnetic flux density of the magnet to predict a future spatial representation of the magnetic flux density and wherein the future spatial representation of the magnetic flux density is compared to the plurality of spatial representations of magnetic flux densities to generate a first performance parameter associated with a current magnet condition and a second performance parameter associated with a future magnet condition.
